(19) United States
(12) Patent Application Publication
(10) Pub. No.: US 2017/0141739 A1
(43) Pub. Date: May 18, 2017

(54) DIGITAL RADIO FREQUENCY AMPLIFICATION SYSTEM

(71) Applicant: ADVANCED WIRELESS SOLUTIONS AND SERVICES (AW2S), Le Bouscat (FR)

(72) Inventor: David ARNAUD, Le Pian Medoc (FR)

(73) Assignee: Advanced Wireless Solutions and Services (AW2S), Le Bouscat (FR)

(21) Appl. No.: 15/127,624

(22) PCT Filed: Mar. 20, 2015
(86) PCT No.: PCT/EP2015/055994

§ 371 Date: Dec. 29, 2016

(30) Foreign Application Priority Data
Mar. 21, 2014 (FR) 1452395

(51) Int. Cl. H03F 1/32; H03F 3/21; H03F 3/19

(52) U.S. Cl. CPC H03F 1/3223; H03F 3/19; H03F 3/21; H03F 1/3241; H03F 2200/451; H03F 2201/3215

(57) ABSTRACT

A digital radio frequency amplification system including a main amplification channel and distortion correction means including a feedforward correction circuit and a pre-distortion correction circuit, the pre-distortion correction circuit including a feedback loop with a first sampling means for sampling a representative signal from the output of the main amplifier to adapt the pre-distortion and minimize errors at the output of the main amplifier, the main amplification channel being supplied by a signal combining a pure useful signal and a pre-distortion signal, the feedforward correction circuit including a first correction channel supplied by a reference signal and transforming same into a first correction signal, the correction channel constituting with the main amplification channel a first loop including a double coupler for sampling an output signal from the main amplification channel and a combination of the output signal with the first correction signal in order to produce a second correction signal.

### CROSS REFERENCE TO RELATED APPLICATIONS

This application is the National Stage of International Application No. PCT/EP2015/055994, having an International Filing Date of 20 Mar. 2015, which designated the United States of America, and which International Application was published under PCT Article 21(2) as WO Publication No. 2015/140323 A1, and which claims priority from, and the benefit of, French Application No. 1452395, filed on 21 Mar. 2014, the disclosures of which are incorporated herein by reference in their entireties.

### BACKGROUND

1. Field

The presently disclosed embodiment relates to the digital radio frequency amplification system comprising a main amplifier and distortion correction circuits

2. Brief Description of Related Developments

Digital radio frequency emitting systems for mobile telephony in particular use a digital pre-distortion system to correct distortion of their amplification stages.

These systems are generally unable to reach the linearity levels required by the amplification of GSM signals except when using costly components for these applications and having low yields.

This is the case especially in repeater applications that must comply with an IMD specification (intermodulation distortion) lower than −36 dBm.

An example of an amplifier device with pre-distortion is described in the document U.S. Pat. No. 8,498,591 B1.

Only systems with “feedforward” amplifiers, an English term that can be translated as amplifiers with correction by anticipation, are, at present, able to achieve these specifications in a commercially acceptable manner.

These systems which include a control system providing a mathematical modeling and compensation for defects prior to the amplification chain have however a very limited yield of around 10%.

Examples of feedforward amplifiers are given for example in documents US 20080252371 A1 and U.S. Pat. No. 6,326,845 B1.

### SUMMARY

In order to improve performance in such circumstances, the presently disclosed embodiment provides a radio frequency amplification system comprising the two corrections that is to say a system with added pre-distortion and a feedforward system.

More specifically the presently disclosed embodiment provides a digital radio frequency amplification system comprising a main amplification channel and distortion correction means for which the distortion correction means includes a correction circuit of the correction by anticipation type called feedforward correction circuit and a pre-distortion correction circuit.

The pre-distortion correction circuit preferably includes a feedback loop with a first means for sampling a signal representative of the output of the main amplifier in order to adjust the pre-distortion and minimize error in the output of the main amplifier.

The main amplifying channel is advantageously powered by a signal combining pure useful signal and a pre-distortion signal, the feedforward correction circuit comprising a first correction channel fed by a reference signal and transforming it into a first correcting signal, said correction channel being, with said main amplifying channel, a first loop which further comprises a double coupler adapted to sample an output signal from the main amplifying channel and a combination of the output signal with the first correction signal to achieve a second correction signal.

Sampling of the signal of the feedback loop of the correction circuit by pre-distortion is advantageously completed downstream of the double coupler of the first loop of the feedforward correction circuit.

The second correction signal is preferably injected into a second correction channel, the second correction channel forming, with a formatting channel extending the main amplifying path, a second loop comprising an output coupler at the general output of the amplification system.

The second correction channel may in particular comprise phase shifting means and amplification means of said second correction signal to generate a final correction signal, the output coupler being designed so as to reinject the final correction signal to said general output of the amplifier, said final correction signal being combined with the output signal at the coupler to generate a cleaned output signal.

The layout channel advantageously includes an insulator and a delay line.

According to an advantageous aspect of the disclosed embodiment, the pure useful signal, the pre-distortion signal and the reference signal are generated within a calculator depending of data input, modeling tables of main amplifier and signals from the feedback loop.

The pure useful signal combined to the pre-distortion may in particular come from a first digital/analog converter.

The reference signal may come from a second digital/analog converter.

The feedback loop advantageously comprises a digital/analog converter.

The signals passing through the amplifier, the feedforward correction circuit and the pre-distortion feedback loop of the correction circuit are advantageously modulated when entering into the amplifier and feedforward device by a carrier by means of a first and a second mixer.

The signal of the feedback loop is in this case preferably demodulated by a carrier at a third mixer.

The system advantageously comprises a second means for sampling the general output.

The system can comprise a third means for sampling the second correction signal.

According to a particular aspect, a three-way switch driven by a control module is adapted to select one or other of the first, second or third means of selection and connect it with the feedback loop, the feedback loop being therefore adapted to serve as means for measuring parameters of operation for all the system correction means.

The control module advantageously drives gain and phase adjusting means for at least one channel of the system.

Advantageously, the control module is part of the calculator which includes a signal processing block, a pre-distortion generation block, a control block of the feedforward loop, the control module controlling said blocks of the calculator.

The pre-distortion correction circuit with its feedback loop allows for a first correction of the signal into the amplifier so that the intermodulation products in the output of the main amplifier are greatly reduced.

The feedforward system itself ensures a second correction step in order to achieve a very high level of linearity.

### BRIEF DESCRIPTION OF THE DRAWINGS

Other features and advantages of the disclosed embodiment will be apparent from reading the description that follows the example of the non-limiting aspects of the disclosed embodiment in reference to the drawings which represent:

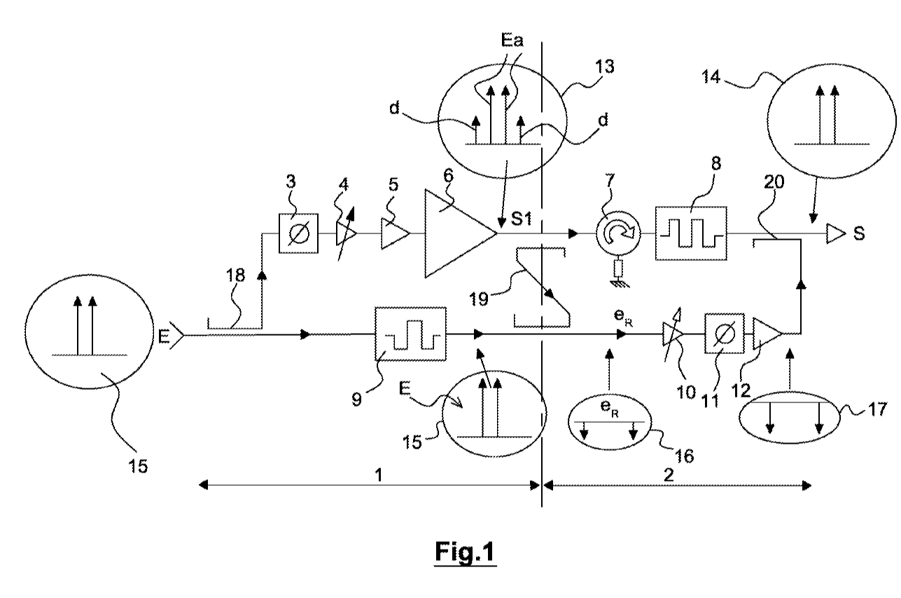

In FIG. 1: a schematic view of an older feedforward correction system;

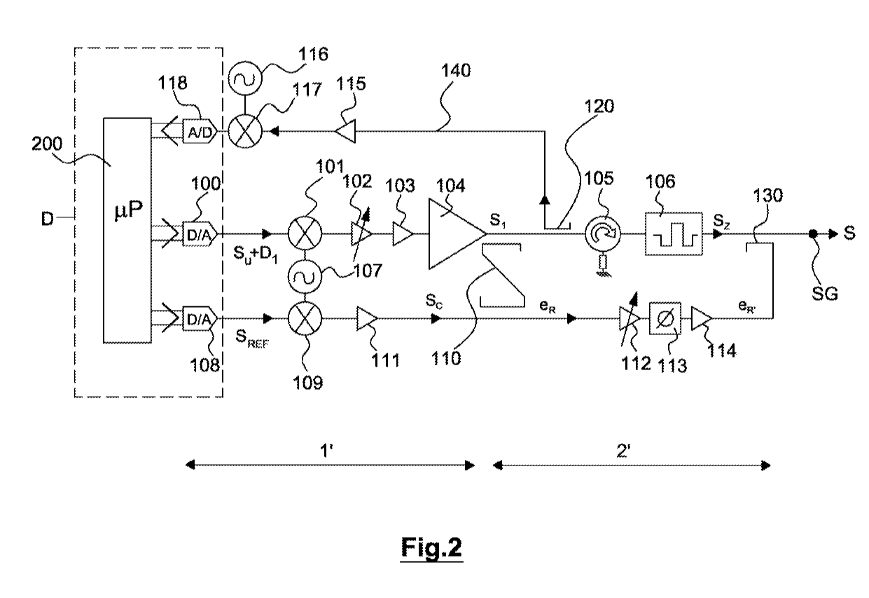

In FIG. 2: a schematic view of a system of the disclosed embodiment combining pre-distortion and feedforward;

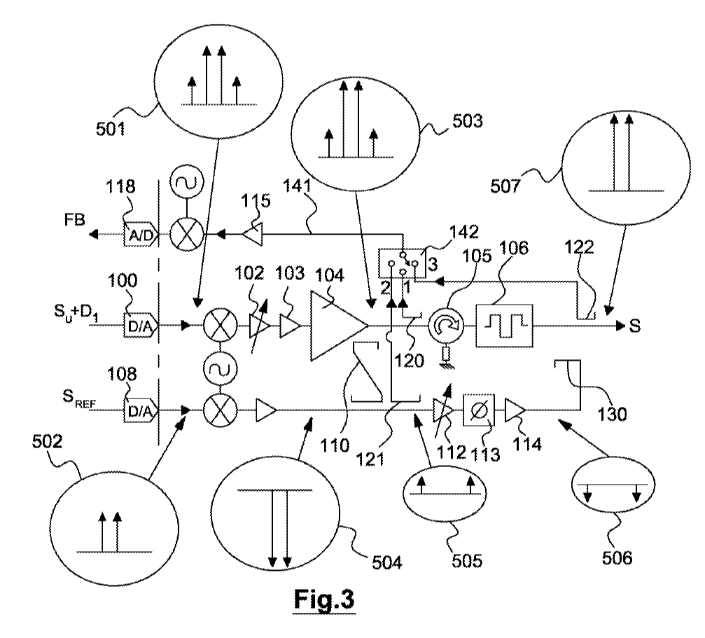

In FIG. 3: the view of FIG. 2 with representation of signal spectra at various points of the schematic;

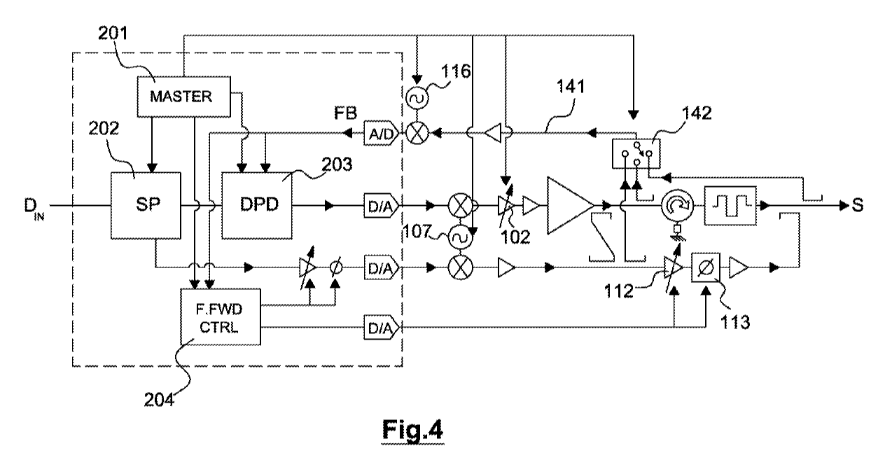

In FIG. 4: the view of FIG. 2 with representation of the computing system controlling both loops of the amplifier.

### DETAILED DESCRIPTION

FIG. 1 schematically represents a prior feedforward amplification system which includes a first loop 1 provided with an input signal E, a divider coupler 18 feeding a first path or amplification channel comprising a phase adjustment 3, a variable gain amplification stage 4 and power amplifier stages 5, 6. At the power output of the amplification channel, a signal S1 is found represented by the spectrum 13 with the amplified input signal Ea and an intermodulation distortion component d. This output is connected to a circulator 7 insulating the output S1 of an antenna output S. Behind the insulator 7 is a delay line 8 for the adaptation phase and a coupler 20 which injects an error signal derived from a second loop 2.

The first loop 1 includes a second channel signal propagating the signal E of spectrum 15 through a delay line or phase shifter 9, which will produce a phase shift identical to the one introduced by the amplifier of the amplification channel, up to a dual coupler 19 which takes a portion of the output signal S1 of the channel amplifier to subtract it from the signal E back into phase so to eliminate the signal E component and generate the error signal e_{R} 16.

This error signal enters the second loop 2 and is amplified by adjustable gain and fixed gain amplification stages 10, 12, phase-shifted by a phase adjustment device 11 to find itself, at the end of the second loop 2, amplified and phase-shifted with the spectrum 17 in opposition phase with the amplifier output signal at the output coupler 20 so that there is a cancellation of the intermodulation products at the antenna output, the spectrum 14 of the output signal S thus being cleaned from distortion.

FIG. 2 schematically represents a device of the disclosed embodiment which improves the FIG. 1 device by adding a digital pre-distortion (Digital pre-distortion DPD D1).

According to this schematics, a first analog-digital converter 100 generates an input signal Su+D1 comprising the useful signal Su combined with a pre-distortion D1 calculated by a calculator 200. This signal is mixed with a carrier 107 in a mixer 101 and then amplified by the amplification stages 102 with variable gain and 103, 104 with fixed gain to give an amplified signal S1.

As in FIG. 1, a path of the first loop 1 processes a reference signal S_{REF} generated here by a second analog digital converter 108, mixed with the carrier 107 at a second mixer then amplified by an amplification stage 111 to be recombined with a sample of the output signal S using a double coupler 110 so to generate an error signal e_{R} that will as in FIG. 1 be treated in a phase shifter 113 and amplification stages 112, 114 to be recombined by means of a coupler 130 in the antenna output of the system with the signal S1 isolated by an insulator 105 and delayed by a delay line 106.

The digital pre-distortion is driven here by a feedback loop 140 which samples a fraction of the amplifier output signal S1, amplifies or adjusts its impedance by means of an amplification stage 115 and then demodulated with the receiving mixer 117 receiving the carrier 116 to then convert it into a digital signal using the analog/digital converter 118. This signal is analyzed by the calculator 200 to adapt parameters of the digital pre-distortion based on the amplifier output signal and its useful range.

This correction ensures that non-linearity of the amplifier has been correctly compensated in the first loop 1′ and that the intermodulation products are only left to be processed in the second loop 2′.

As for the digital pre-distortion, the digital/analog converter D/A 100 is used for generating the useful signal in pre-distorted baseband Su+D1 that will be amplified and will linearize the main amplifier.

The analog-digital converter A/D 118 in the feedback loop 140 provides correction data used to implement a dynamic adaptation of the pre-distortion based on the amplifier output signal and improve this first correction.

Regarding the feedforward system, the reference signal S_{REF}, used to be subtracted from the useful signal in the main amplifier output so as to generate the error signal in the second loop, is numerically driven in phase and amplitude to eliminate the useful signal input of the second loop.

The error signal e_{R} is, after amplification and being set back into opposition of phase, subtracted from the RF output signal of the entire amplifier.

In practical terms, cancellation couplers are between 7 and 12 dB coupling attenuation, sampling ones between 20 and 30 dB of attenuation and the various stages are designed to offset these attenuations and adjust the signals back to scale.

Also according to FIG. 2, the system is driven by a calculator implemented in for example an FPGA device and the first feedforward loop is entirely digital, the adjustment of the level of the reference signal and its relative phase with the pre-distorted signal is implemented inside the FPGA in a digital manner.

FIG. 3 represents a variation of the system in FIG. 2 which includes the first means 120 for sampling the main amplifier output signal and which further comprises a second means 122 for sampling the general output signal and a third means 121 for sampling the second e_{R} correction signal.

A three-way switch 142 driven by a control module 201 shown in FIG. 4 is adapted to select one or the other of the first, second or third means of selection and connect it with the feedback loop 141, the feedback loop being adapted to serve as means for measuring operating parameters of all correction means of the system.

According to the example, the analog-digital converter A/D 118 in the feedback loop is also used to achieve the convergence of the first and second loop of the feedforward system by allowing the analysis of this signal in the output of the main amplifier, at the entrance of the second error correction loop and the general output of the amplifier.

To complete the digital processing of feedforward, two converters, one delivering a useful signal combined to a pre-distortion digital signal, the other providing a reference signal are used.

Sampling by the third means 121 at the entrance to the second error correction loop is used here to verify that this signal presents minimal correlation with the reference signal S_{REF} to adjust at best the alignment of the reference signal and the signal output from the main amplifier. Indeed, only the intermodulation products must be present at the entry of the error amplifier and the signal thus present a minimal correlation when the useful signal is completely subtracted from the output signal.

A verification method can consist in analyzing the spectrum of the signal input of the amplifier and the one at the entrance of the second error correction loop to check for the absence of carriers in the second of these signals.

Sampling by the second means 122 measures the output signal after corrections.

The convergence of the second loop is made by regulating the phase and gain of the error amplifier at the phase shifter 113 and the adjustable gain amplification stage 112. To optimize this result, the amplifier output is analyzed and two methods can be used, the first is a frequency analysis of the output signal to control the level of intermodulation, the second is to maximize the correlation between the reference signal and the output which corresponds to a minimum intermodulation.

The three-way switch 142 is adapted to select one or the other of first, second or third means of selection and connects it with the feedback loop 141 that serves as a means of measuring operating parameters of all correction means of the system.
Position 1 of the switch in which the return path is connected to the sampling means 120 is used to observe the linearization of the main amplifier and to have the digital pre-distortion algorithm converge,
Position 2 for which the return path is connected to sampling means 121 is used to analyze the input of the error loop and accordingly to check that there is no more useful signal and that only the intermodulation products remain. This is achieved by aligning gain and phase of both branches of the first loop, these controls are set inside the signal processor before the analog digital converter reference.
Position 3 for which the return path is connected to the sampling means 122 is used to analyze the output signal of the final amplifier to verify the correction of the feedforward system. This correction is achieved by regulating the alignment gain and phase of the second loop using shifters attenuators present in this latter.

These three actions can be done in a sequential manner or be implemented according to set operating conditions of the amplifier.

The signals spectrums are shown on FIG. 3.

Signals are represented
as entry into the main amplifier 501 where the signal comprises the central stripes of the useful signal and the lateral stripes of pre-distortion;
as entry into the first feedforward correction loop 502 or only central stripes of useful reference signal are presented;
as output of the main amplifying path 503 where the lateral stripes now only include intermodulation distortion;
as amplifier output; as entry in the correction channel of the second feedforward loop 505 where the stripes of the useful signal are removed during the coupling of the reference signal with the amplifier output signal to leave only the stripes of the intermodulation distortion signal;
At the end of the correction channel of the second loop 506 where intermodulation distortion was shaped to be subtracted out of the system and;
The output of the system 507 where only the stripes of the useful amplified signal are present.

FIG. 4 represents the complete system with its detailed control calculator 200.

The calculator 200 comprises several blocks or calculation functions that will generate the necessary data to generate the pure useful signal Su, the pre-distortion signal D1 and the reference signal S_{REF} depending on a data input D to be issued, modeling tables of the main amplifier and the signals from the feedback loop 141.

The calculator according to the example includes in particular a signal processing block SP (signal processing) 202, a pre-distortion generation block DPD (digital pre-distortion) 203, a control block of the feedforward loop F.FWD CONTROL 204. These blocks generate data aiming to be converted to generate the above signals.

The calculator further controls the three-way switch 142 through a control module MASTER 201 adapted to select one or the other of the first, second or third means of selection and connect it with the feedback loop 141.

The control module 201 further drives the gain adjustment means 102 of the main channel and the gain and phase adjustment means 112, 113 of the error correction channel of the second feedforward loop.

Driving the adjustment means can be done using digital analog converters and analog outputs of the calculator driven by the control module.

The control module 201 further drives, according to the example, all blocks of the calculator and the carriers 108, 116.

The system is therefore seen from the user as an amplifier block receiving data D to be issued, the calculator taking care of controlling all the parameters of operation of the amplifier of the transmitter.

The calculator can be made of a microcontroller associated to digital/analog D/A converters and analog/digital A/D integrated or discrete but a preferred solution is to integrate all calculator converters and control channels in a FPGA component (field programmable gate array) or dedicated logic programmable network comprising cables blocks for processing DSP, an embedded microprocessor core, one or more blocks of synthesis and/or timing of clocks, conversion blocks A/D and D/A, the controlled memory impedances inputs/outputs and other resources necessary to control the amplifier and data transmission.

The disclosed embodiment makes it possible to use a low linear but high yield amplifier, e.g. a “Doherty” type amplifier.

The disclosed embodiment is not limited to the examples represented, including the fact of using a digital signal treated by an amplifier management calculator to add other processes to the digital signal either by calculation blocks or by software in the calculator such as a crest factor reduction which further improves the overall efficiency of the system.

What is claimed is:

1. A digital radio frequency amplification system including a main amplifying channel and distortion correction means, the distortion correction means include a correction circuit of the correction by anticipation type, called feedforward correction circuit, and a pre-distortion correction circuit, the pre-distortion correction circuit including a feedback loop equipped with first means for sampling a signal representative of the output of the main amplifier in order to adjust the pre-distortion and minimize the error in output of the main amplifier, the main amplifying channel being powered by a signal combining a pure useful signal and a pre-distortion signal, the feedforward correction circuit comprising a first correction channel powered by a reference signal and transforming it into a first correction signal, said correction channel being with said main amplifying channel a first loop which further comprises a double coupler adapted to sample an output signal of the main amplifying channel and a combination of the output signal with the first correction signal to achieve a second correction signal.

2. The digital radio frequency amplification system according to claim 1, wherein sampling of the signal from the feedback loop of the pre-distortion correction circuit is completed downstream of the double coupler of the first loop of the feedforward correction circuit.

3. The digital radio frequency amplification system according to claim 1, comprising a second correction channel in which the second correction signal is injected, said second channel forming a second correction loop, with a formatting channel extending the main amplifying channel, said second loop comprising an output coupler at a general output of the amplification system.

4. The digital radio frequency amplification system according to claim 3, wherein the second correction means includes phase shifting means and amplifying means of said second correction signal to generate a final correction signal, the output coupler being designed so as to reinject the final correction signal at said general output of the amplifier, said final correction signal being combined with the output signal at the coupler to generate a cleaned output signal.

5. The digital radio frequency amplification system according to claim 3, wherein the formatting means comprises an insulator and a delay line.

6. The digital radio frequency amplification system according to claim 1, wherein the pure signal, the pre distortion signal and the reference signal are generated in a calculator depending on a data input, modeling tables of the main amplifier and the signals from the feedback loop.

7. The digital radio frequency amplification system according to claim 6, wherein the pure useful signal combined to the pre-distortion originates from a first digital/analog converter.

8. The digital radio frequency amplification system according to claim 6, wherein the reference signal originates from a second digital/analog converter.

9. The digital radio frequency amplification system according to claim 1, wherein the feedback loop includes a digital to analog converter.

10. The digital radio frequency amplification system according to claim 1, wherein the signals passing through the amplifier, the correction feedforward circuit and feedback loop of pre-distortion correction circuit are modulated by a carrier the entry of the amplifier and of the feedforward device by means of a first and a second mixers.

11. The digital radio frequency amplification system according to claim 10, wherein the signal of the feedback loop is demodulated by a carrier at a third mixer.

12. The digital radio frequency amplification system according to claim 1, comprising a second means for sampling the general output signal.

13. The digital radio frequency amplification system according to claim 1, further comprising a third means for sampling the second correction output signal.

14. The digital radio frequency amplification system according to claim 1, wherein a three way switch driven by a control module is adapted to select one or other of the first, second or third means of selection and connect them to the feedback loop, the feedback loop being adapted to serve as a means for measuring operating parameters of all correction means of the system.

15. The digital radio frequency amplification system according to claim 14, wherein the control module drives the gain and phase adjustment means for at least one channel of the system.

16. The digital radio frequency amplification system according to claim 6, wherein the control module is part of the calculator which includes a signal processing block, a pre distortion generation block, a control block of the feedforward loop, the control module controlling said blocks of the calculator.
